(19) United States
(12) Patent Application Publication
(10) Pub. No.: US 2010/0028107 A1
(43) Pub. Date: Feb. 4, 2010

(54) APPARATUS AND METHOD FOR SUCCESSIVELY TRANSPORTING A PLURALITY OF GSM CHIP CARDS

(75) Inventors: Christian Dobler, Waffenbrunn (DE); Alexander Goedecke, Bernhardswald-Pettenreuth (DE); Thomas Valta, Schorndorf (DE)

Correspondence Address: BLACK LOWE & GRAHAM, PLLC, 701 FIFTH AVENUE, SUITE 4800, SEATTLE, WA, 98104, US

(73) Assignee: Muehlbauer, AG, Roding (DE)

(21) Appl. No.: 12/298,758

(22) PCT Filed: Apr. 25, 2007
(86) PCT No.: PCT/EP07/54026

§ 371 Date: May 1, 2009

(30) Foreign Application Priority Data
Apr. 28, 2006 (DE) 10 2006 019 785.2

(51) Int. Cl. H01L 21/677

(52) U.S. Cl. 414/222.07; 414/806

(57) ABSTRACT

Devices and methods for successively transporting a plurality of cards arranged in a row, in particular GSM chip cards, between at least one feed path and a first tray element which can be displaced perpendicular to the orientation of the feed path, by means of at least one transfer station within a card processing device, wherein the transfer station comprises at least two transport elements for picking up and depositing individual cards, said transport elements being able to be rotated about a respective axle running perpendicular to the plane of the feed path and of the first tray element, wherein the transport elements can be moved back and forth along the orientation of the first tray element and a second tray element which can be displaced in the direction of the first tray element.

### FIELD OF THE INVENTION

The invention relates to a device and method for successively transporting a plurality of cards arranged in a row, in particular GSM chip cards, between at least one feed path and a first tray element which can be displaced perpendicular to the orientation of the feed path, by means of at least one transfer station within a card processing device, according to the preambles of claims 1 and 7.

### BACKGROUND OF THE INVENTION

Devices for successively transporting a plurality of cards arranged in a row, such as chip cards, between at least one feed path and a first tray element which can be displaced perpendicular to the orientation of the feed path, by means of a transfer station, are known within card processing devices which are used primarily for encoding a large number of cards. To this end, cards 3 are continuously transported on a feed path 2 in the arrow direction 4 from left to right within a card processing device 1, as shown in FIG. 1 according to the prior art, and are distributed between several rows of processing paths 5a-5d comprising numerous encoding stations 6 for encoding the chip cards 3.

The cards are fed individually to the individual processing paths 5a-5d, on a displaceable tray element 8a which can be displaced back and forth on a transport rail 7a, as shown by reference 9a.

In the same way, the encoded cards are passed back from the processing paths to the feed path 2 in the direction 9b via a transport rail 7b by means of a further tray element 8b, which is designed as a transport carriage.

In order to distribute the cards 3 placed on the feed path 2 between the processing paths 5-5d arranged parallel to the feed path, the card 3 moving in the direction 4 is transferred by means of a transfer station 10a onto the transport carriage 8a moving in the direction 9a.

To this end, the cards 3 arriving on the feed path 2 are separated in such a way that they can be transferred individually onto the transport carriage, which then moves with this individual card towards the desired processing path 5a-5d. The processing path receives the card in a manner not shown in any greater detail here and assigns it to an encoding space 6.

In such a procedure, there is necessarily a pause during which the transport carriage permits no further operating step of the processing system as it returns to the transfer station 10a without any card to be transported. Likewise, a transfer pause within the transfer station is necessary for the card to be transferred from the feed path 2 to the transport carriage 8a or from the transport carriage 8b to the feed path 2, namely once the transport carriage has returned empty to the transfer station. This results in a limited throughput of the processing system as a whole, even if a large number of processing paths are provided for simultaneously encoding the cards.

The transfer stations 10a, 10b are arranged to the side of the processing paths 5a-5d within which the card is encoded. Accordingly, the time taken by the transport carriage 8a to reach the outermost processing path 5a is greater than the time taken to reach the processing path 5d. This results in long waiting times within each operating cycle, during which the transfer station has to wait on the returning carriage in order to further load it with a card.

Accordingly, the object of the present invention is to provide a device and method for successively transporting a plurality of cards arranged in a row between at least one feed path and a first tray element which can be displaced perpendicular to the orientation of the feed path, by means of at least one transfer station, in which the cards arriving on the feed path can be rapidly fed to individual processing paths and rapid transfer back from the processing paths to the feed path is possible.

### SUMMARY OF THE INVENTION

This object is achieved in terms of the device by the features of claim 1 and in terms of the method by the features of claim 7.

One essential point of the invention consists in that, in a device for successively transporting a plurality of cards arranged in a row, in particular GSM chip cards, between at least one feed path and a first tray element which can be displaced perpendicular to the orientation of the feed path, by means of at least one transfer station within a card processing device, the transfer station comprises at least two transport elements for picking up and depositing individual cards, said transport elements being able to be rotated about a respective axle running perpendicular to the plane of the feed path and of the first tray element. The transport elements can be moved back and forth along the orientation of the first tray element and a second tray element which can be displaced in the direction of the first tray element. During this back-and-forth movement, the transport elements are rotated through 90° so that the card which is originally oriented in the movement direction of the feed path is automatically rotated into the displacement direction of the tray elements which is perpendicular thereto during transport of the card from the feed path to one of the tray elements.

Since the first and second tray elements are arranged on both sides of the transfer station, and not just on one side, the cards coming from the feed path can be alternately deposited on the first and second tray element due to the arrangement of a total of two transport elements within a module of the transfer station. This leads to a rational and time-saving transfer of the cards from the feed path to the individual tray elements, which are then displaced on transport rails so as to bring the cards to the individual processing paths with the encoding stations contained therein.

Ideally, such a distribution of the cards within the transfer station between a total of two tray elements means that the transfer station is controlled in such a way that a card is being deposited on one of the tray elements by one transport element while the other transport element during this time is picking up a further card from the feed path, which of course can be any type of feed unit, for example for feeding in stacks of cards. This ensures that the cards are continually supplied to the displaceable tray elements and of course also that further tray elements are continually being picked up and supplied to the feed path at the exits of the processing paths. The time during which one of the tray elements is moving from a processing path back to the transfer station can thus be used to equip the transfer station with the further tray element.

The first and second tray elements can ideally be displaced in opposite directions on a common plane starting from opposite sides of the transfer station.

The module arranged in the transfer station is moved back and forth within the transfer station in order to reach the individual displaceable tray elements, which are in their starting position, with its transport elements, which are arranged within the module. During this back-and-forth movement, which is carried out by means of a toothed belt drive arranged in the transfer station, the 90° rotation of the transport elements takes place at the same time, which transport elements are ideally also arranged such that they are pivoted through 90° with respect to one another. To this end, the two transport elements are connected via a gearwheel mechanism to a gearwheel rail arranged in a stationary manner in the transfer station.

Of course, all the alternative transmission mechanisms, such as by means of a belt or the like, can also be used in order to perform a 90° rotation of the transport elements. However, the use of a gearwheel mechanism ensures precise and accurate positioning of the transport elements and thus of the chip cards with respect to the tray elements and placement positions on the feed path.

The transport elements are preferably height-adjustable, in order to pick up the cards fed through below the module from the feed path and then to deposit them on the tray element which can be displaced perpendicular thereto.

In a method for successively transporting a plurality of cards arranged in a row, the cards are alternately picked up by at least two transport elements, then rotated through 90° about a respective axle running perpendicular to the plane of the feed path and of the first tray element, and alternately deposited. This can take place with a time offset in such a way that one card is being picked up just as the other card is being deposited.

The transport elements, during their rotational movement, are preferably moved back and forth along the orientation of the first tray element and of a second tray element which can be displaced in the direction of the first tray element.

The feed path, during the rotational movements of the transport elements and during their back-and-forth movement, is preferably moved further in the direction of the transfer station in steps of one card position, so that a further card can be removed from the feed path.

Further advantageous embodiments emerge from the dependent claims.

### BRIEF DESCRIPTION OF THE DRAWINGS

Advantages and expedient features can be found in the following description in conjunction with the drawings.

FIG. 1 shows a schematic plan view of a chip card processing system with a transport device according to the prior art, as already described;

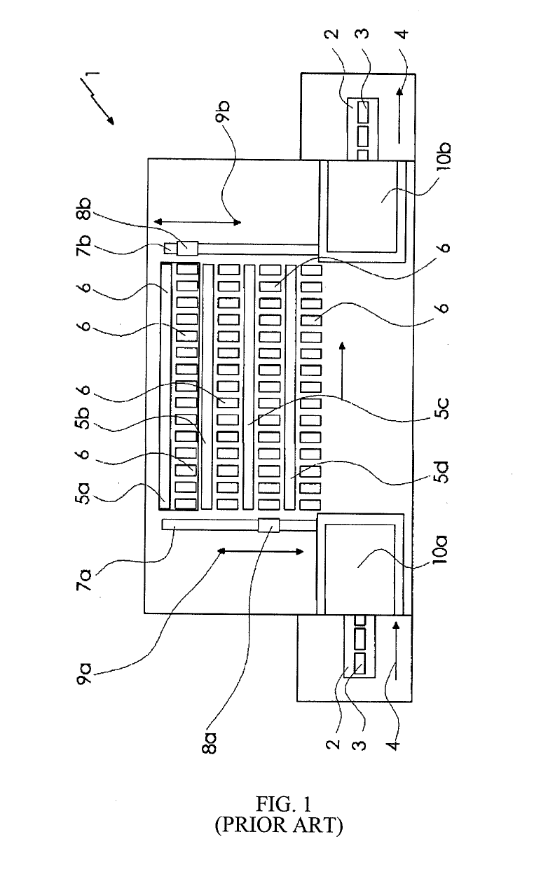

FIG. 2 shows a schematic plan view of a chip card processing system with a device according to the invention for successively transporting a plurality of cards arranged in a row, according to one embodiment of the invention;

FIG. 3 shows a perspective view of part of the transfer station for use in the device according to the invention;

FIG. 4 shows a schematic simplified diagram in plan view of part of the device according to the invention, and

FIG. 5 shows a schematic simplified diagram in plan view of part of the device according to the invention, according to a further embodiment of the invention.

### DETAILED DESCRIPTION OF THE PREFERRED EMBODIMENT

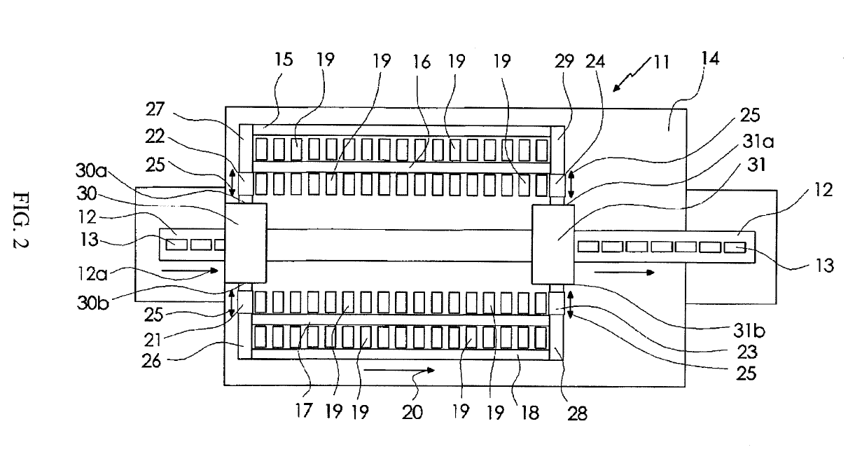

FIG. 2 shows a schematic diagram in plan view of a card processing system or card processing device 11. In this card processing device 11, a feed path 12 is displaced in steps from left to right as seen in the plan view shown in the drawing. The feed path 12 contains a plurality of cards 13 arranged in a row, which are further moved by the feed path 12 in the arrow direction 12a.

In a processing unit 14, the cards 13 are allocated and fed to individual processing paths 15-18 which have a plurality of encoding stations 19 arranged in rows for encoding the cards. To this end, according to the invention the processing paths are arranged to the left and to the right of the feed path 12, as seen in the feed direction 12a of the feed path 12.

The cards pass through the processing paths from one end side of the processing paths to the other, as indicated by the arrow 20. The encoded cards are then picked up from the processing paths and deposited on the feed path 12.

The feeding of the cards 13 from the feed path 12 to the individual processing paths 15-18 takes place by means of displaceable tray elements 21, 22, which as card carriages are displaced on a respective rail 26, 27. This is illustrated by the arrow shown as reference 25.

The cards 13 that have already been encoded are also returned from the processing paths 15-18 on further displaceable tray elements 23, 24 which as card carriages can be displaced on the rails 28, 29. This is once again shown by the double arrows bearing reference 25.

The cards 13 are transferred from the feed path to the tray elements 21, 22 and from the tray elements 23, 24 back to the feed path 12 within transfer stations 30, 31 which at their opposite sides 30a, 30b on the one hand and 31a, 31b on the other hand have a connection to the rails 26, 27 and 28, 29 running in opposite directions.

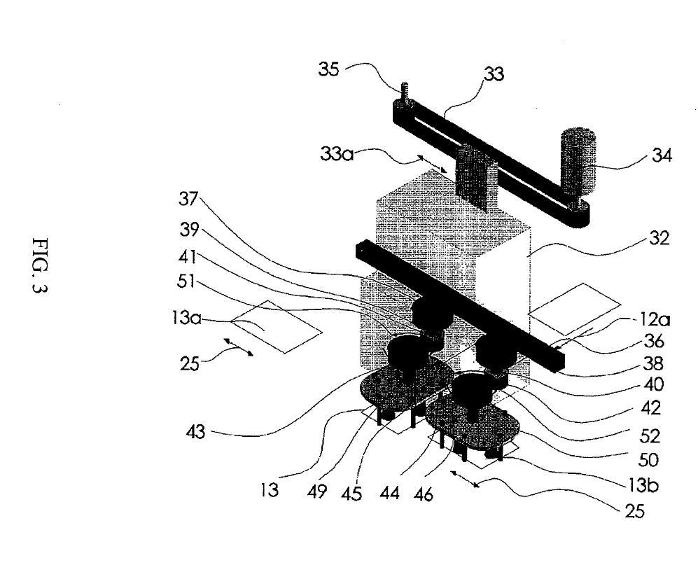

In the transfer stations 30, 31, the cards 13 are distributed between two card carriages instead of just one by means of a module (shown in FIG. 3). Via this module, one card is deposited on one of the carriages while a further card still located on the feed path is picked up from the feed path during this time. Such forced control results in a considerable reduction in the time taken to transfer the cards onto the carriages and rails which can be displaced perpendicular to the feed path 12.

An example of the time-optimized transfer of the cards within the transfer station will now be demonstrated with reference to FIG. 3, which shows part of a transfer station in perspective view.

A module 32 is moved back and forth by means of a gearwheel belt 33 which can also move back and forth in the direction of the double arrow 33a by means of a motor 34 and a deflection roller 35. The gearwheel belt is arranged in a stationary manner within the transfer station, whereas the module 32 is arranged such that it can be displaced in the direction of the double arrow 33a.

A gearwheel rail 36 which is also arranged in a stationary manner makes it possible for gearwheels 37, 38 to be rotated while the module is moved back and forth, said gearwheels and the gearwheel mechanism 37-46 as a whole being connected to the module.

The gearwheels 37, 38 act via axles 39, 40 connected thereto and further gearwheels 41, 42 on gearwheels 43, 44 which in turn are connected by means of axles 45 and 46 to the module.

Rotation of the gearwheels 37, 38 and thus of the gearwheels 43, 44 thus brings about rotation of the axles 45, 46, to which transport elements 49, 50 are attached. This is illustrated by the arrows 51, 52.

When a card 13 arriving on the feed path 12 in the feed direction 12a is picked up by the first transport element 49, a movement of the module 32 to the left as seen in the image plane then takes place, during which there is a simultaneous rotational movement 51, 52 of the axles of the two transport elements. The first transport element 49 thus carries out a 90° rotation with the card 13 adhering thereto, and after the movement of the module 32 to the left deposits it as card 13a onto a first tray element (not shown here). The first tray element then moves in the direction of the double arrow 25 on a rail (not shown here) in order to feed the card 13a to a selected processing path (also not shown here).

At the same time, a rotation 52 of the second transport element 50 takes place during its movement to the left, so that it is oriented in the card direction of the cards 13 arranged on the feed path 12 at the time it comes to rest above the feed path. A further card is then picked up which, after a return linear movement of the module 32 and a simultaneous rotational movement of the second transport element 50 and of the first transport element 49, is deposited as card 13b on a first tray element (not shown here).

Such forced control is made possible by the fact that the motor 34 controls the running direction of the module 32.

The cards 13 are transported through below the module on the feed path 12 (not shown in any detail here). The transport elements 49, 50, which have exert a suction grip, can thus access the cards 13 and pick them up or deposit them on the feed path.

The transporting of the cards on the feed path 12 takes place in a step-by-step manner, i.e. the feed path 12 is moved forward by the distance of one card in order for it to be picked up by one of the transport elements or gripper elements. The module is then moved back and the transport element changes its orientation by virtue of a 90° rotation. At the same time, the orientation of the further transport element is changed in order to deposit a card.

While the first transport element 49 is arranged above the tray element in order to deposit a card, the second transport element 50 has again rotated into a card pick-up position along the orientation of the feed path 12 in order to pick up a card from the latter. During this rotational movement, the feed path is further transported by precisely one card position.

The rate of transfer of the cards is controlled inter alia by the gearwheel mechanism and its connection to the gearwheel rail and also the speed of the toothed belt.

The throughput of the card processing system can advantageously be increased by simultaneously picking up and depositing two cards. It is thus no longer necessary to schedule a waiting time within the transfer station in order to await the return of the transport carriage to pick up a further card.

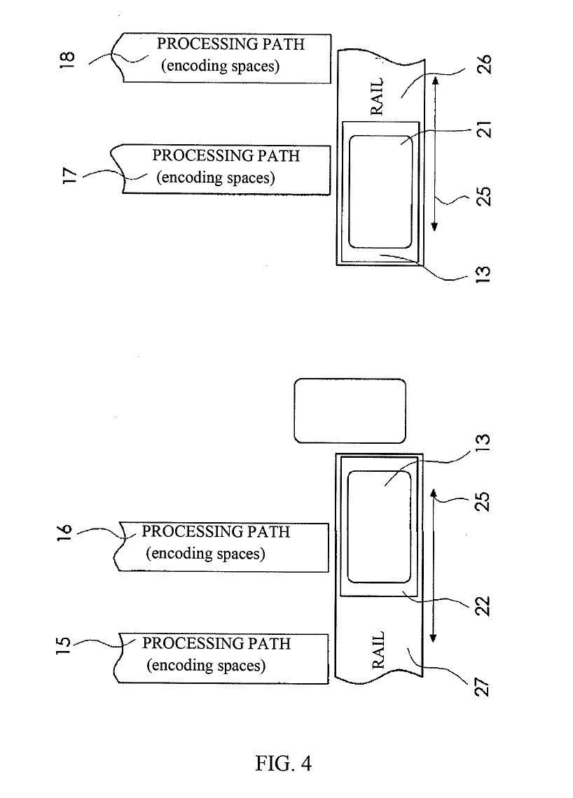

FIG. 4 shows a simplified schematic diagram of the functioning of the card processing system with the feed path (not shown). The individual processing paths 15, 16, 17 and 18 are approached in the arrow direction 25 by the first tray element 21 and the second tray element 22 and the rails 26, 27.

The processing paths 15-18 running at right angles to the orientation of the rails 26, 27 are also approached at their other ends (not shown here) by further tray elements and rails arranged there beneath, after a card personalization process, in order then to arrive at a further transfer station for transferring the cards back to the feed path 12 by means of a further module. Here, the cards are alternately picked up from the tray elements by further transport elements and fed to a transport device, such as the feed path. From there, the cards pass either into a magazine or to another processing station.

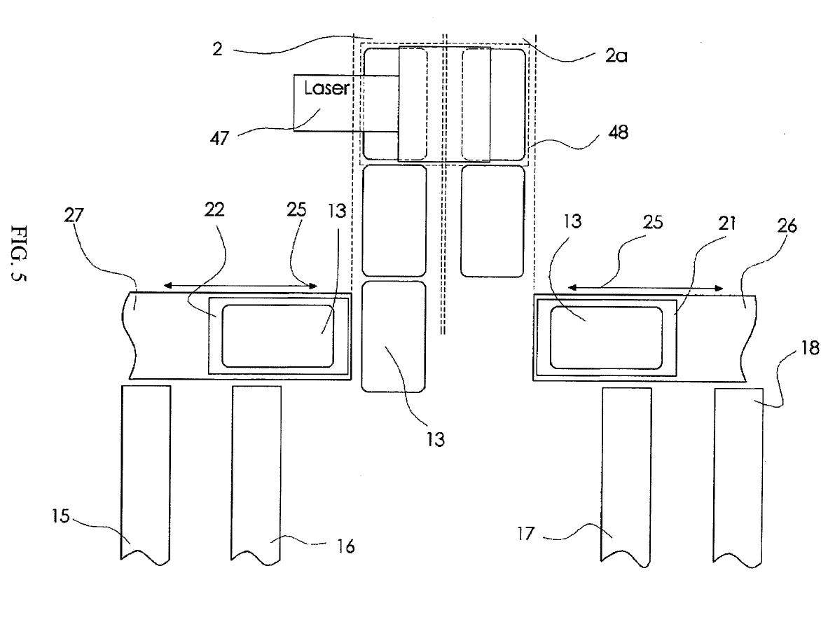

FIG. 5 shows a simplified schematic diagram in plan view of the card processing system in the end region in which the cards are transferred back from the rails 26, 27 to two continuing feed paths 2, 2a. The individual processing paths 15, 16, 17 and 18 are approached in a sliding manner in the arrow direction 25 by the first tray element 21 and the second tray element 22 on the rails 26, 27.

This embodiment shown in FIG. 5 differs from the embodiment shown in FIGS. 3 and 4 in that the first and second transport elements 49, 50 are spaced further apart from one another. This is not shown in FIG. 5. On account of the two transport elements being spaced further apart, it is possible to load not just one feed path but rather two feed paths 2, 2a running parallel to one another alternately with the cards 13 arriving from the tray elements 21, 22, without this giving rise to any loss of time in comparison to the embodiment shown in FIGS. 4 and 3.

By virtue of the loading of two parallel paths 2, 2a in the discharge area of the card processing system, it is possible for the time-intensive laser machining of the surfaces of the cards 13 to take place alternately in a common laser field 48 by means of one laser 47. This results in a reduction in the laser machining time and thus in a higher throughput of the system as a whole. Alternatively, two laser machining systems could of course be provided, namely one for the path 2 and one for the path 2a, in order to carry out the laser machining on the cards simultaneously.

The device according to the invention advantageously has a synchronous transfer of the cards and also advantageously a symmetrical encoding space arrangement with respect to the transfer station. This results in a much faster transfer process and consequently in a rapid personalization process.

All the features disclosed in the application documents are claimed as essential to the invention in so far as they are novel individually or in combination with respect to the prior art.

### LIST OF REFERENCES

1 card processing system
2, 2a feed paths
3 cards
4 feed path movement direction
5a-5d card processing paths
6 encoding station
7a, 7b rails
8a, 8b displaceable tray element
9a, 9b displacement direction of the tray elements
10a, 10b transfer stations
11 card processing system
12 feed path
12a feed path movement direction
13 cards
13a, 13b cards
14 card processing station
15, 16, 17, 18 card processing paths
19 encoding stations
20 processing direction
21, 22, 23, 24 displaceable tray elements
25 movement direction
26, 27, 28, 29 rails
30, 31 transfer stations
30a, 30b, 31a, 31b sides of the transfer stations
32 module
33 gearwheel belt
33a movement direction of the gearwheel belt
34 motor
35 deflection roller
36 gearwheel rail
37-46 gearwheel mechanism
47 laser
48 laser field
49, 50 first and second transport element
51, 52 directions of rotation

1. A device for successively transporting a plurality of cards arranged in at least one row, between at least one feed path and a first tray element which can be displaced perpendicular to the orientation of the feed path, at least device comprising:
at least two transport elements for picking up and depositing individual cards, said transport elements being able to be rotated about a respective axle running perpendicular to the plane of the at least one feed path and of the first tray element, wherein the transport elements are moveable back and forth along the orientation of the first tray element; and
a second tray element which can be displaced in the direction of the first tray element.

2. The device according to claim 1, wherein first and second tray elements are displaceable in opposite directions on a common plane starting from opposite sides of the transfer station.

3. The device according to claim 1, wherein in that the transfer station includes a module which can be moved back and forth in the direction of the displaceable tray elements and in which the transport elements are arranged.

4. The device according to claim 3, wherein the transfer station has a toothed belt drive for carrying out the back-and-forth movement of the module.

5. The device according to claim, wherein the two transport elements are connected via a gearwheel mechanism to a gearwheel rail for carrying out their rotational movements, said gearwheel rail being arranged in a stationary manner in the transfer station.

6. The device according claim 1, wherein the transport elements are height-adjustable.

7. A method for successively transporting a plurality of cards arranged in a row between at least one feed path and a first tray element which is displaceable perpendicular to the orientation of the feed path, by means of at least one transfer station within a card processing device, the method comprising: alternately picking up the cards by at least two transport elements,
rotating the transport elements through 90° about a respective axle running perpendicular to the plane of the feed path (12) and of the first tray element (22, 24) and
alternately depositing the cards.

8. The method according to claim 7, wherein rotating comprises moving the transport elements back and forth along the orientation of the first tray element and of a second tray element which is displaced in the direction of the first tray element.

9. The method according to claim 7, wherein the first transport element picks up a card from the feed plane or from one of the displaceable tray elements while the second transport element deposits a further card on one of the displaceable tray elements or on the feed path.

10. The method according to one of claims 7, further comprising rotating the first transport element through 90° with respect to the second transport element.

11. The method according to claim 7, wherein rotating comprises moving the feed path further in the direction of the transfer station in steps of one card position.

12. The device according to claim 1, wherein the plurality of cards comprises a plurality of GSM chip cards.

13. The method according to claim 7, wherein the plurality of cards comprises a plurality of GSM chip cards.
